(19) United States
(12) Patent Application Publication
(10) Pub. No.: US 2026/0020145 A1
(43) Pub. Date: Jan. 15, 2026

(54) FLEXIBLE CIRCUIT BOARD, DISPLAY MODULE AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Mi Zhang, Beijing (CN); Hengzhen Liang, Beijing (CN); Hang Min, Beijing (CN); Lianbin Liu, Beijing (CN); Wenxiao Niu, Beijing (CN); Yi Tao, Beijing (CN); Hui Zhao, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/881,021

(22) PCT Filed: May 21, 2024
(86) PCT No.: PCT/CN2024/094322

§ 371 Date: Jan. 3, 2025

(30) Foreign Application Priority Data
Jun. 13, 2023 (CN) 202310700882.1

(51) Int. Cl. H05K 1/02; H02H 9/00; H02H 9/04

(52) U.S. Cl. CPC H05K 1/0259; H02H 9/005; H02H 9/04; H05K 1/0277; H05K 2201/0746; H05K 2201/10128

(57) ABSTRACT

A flexible circuit board, a display module and a display device are provided. The flexible circuit board includes: an electrostatic discharge protection circuit, an electrostatic discharge detection circuit and a switch circuit; an input end of the electrostatic discharge detection circuit is coupled to an output end of the electrostatic discharge protection circuit, and an output end of the electrostatic release detection circuit is coupled to a control end of the switch circuit; a first end of the switch circuit, a reset signal output end of an application processor, and a reset signal input end of a Display Driver Integrated Circuit (DDIC) are coupled to the first node, and a second end of the switch circuit is coupled to a ground.

### CROSS-REFERENCE TO RELATED APPLICATION

The present disclosure claims priority to Chinese Patent Application No. 202310700882.1 filed in China on Jun. 13, 2023, the entire contents of which are incorporated herein by reference.

### TECHNICAL FIELD

The present disclosure relates to the technical field of circuit board design, and in particular, to a flexible circuit board, a display module, and a display device.

### BACKGROUND

At present, display devices are increasingly used in life to meet people's various needs in entertainment, social interaction and business, so the update and development of display devices are also getting faster and faster. Organic Light-Emitting Diode (OLED) display panels have received a lot of attention due to their advantages in narrow borders and high screen-to-body ratio. However, the inventors found that the OLED display panels in the related art have insufficient Electro-Static Discharge (ESD) resistance capability.

### SUMMARY

An object of the present disclosure is to provide a flexible circuit board, a display module and a display device to solve at least one of the problems in the prior art.

In order to achieve the above object, the present disclosure adopts the following technical solutions.

In a first aspect, the present disclosure provides a flexible circuit board, including an electrostatic discharge protection circuit, an electrostatic discharge detection circuit, and a switch circuit;
an input end of the electrostatic discharge detection circuit is coupled to an output end of the electrostatic discharge protection circuit, and an output end of the electrostatic discharge detection circuit is coupled to a control end of the switch circuit;
a first end of the switch circuit, a reset signal output end of an application processor, and a reset signal input end of a Display Driver Integrated Circuit (DDIC) are coupled to a first node, and a second end of the switch circuit is coupled to a ground.

Optionally, the switch circuit comprises a first switch transistor, a control electrode of the first switch transistor is coupled to the output end of the electrostatic discharge detection circuit, a first electrode of the first switch transistor is coupled to the first node, and a second electrode of the first switch transistor is coupled to the ground.

Optionally, the first switch transistor is an N-type transistor.

Optionally, the flexible circuit board further includes a first resistor and a first capacitor, the first resistor is coupled between the reset signal output end of the application processor and the first node, the first end of the first capacitor is coupled to the first node, and the second end of the first capacitor is coupled to the ground.

Optionally, the flexible circuit board comprises a first binding area that is located at an end position on one side of the flexible circuit board and used for binding a display panel, and at least a portion of the flexible circuit board adjacent to the first binding area comprises a first ground layer, a wiring layer, and a second ground layer that are laminated sequentially in that order.

Optionally, the first ground layer and the second ground layer are electrically connected through a via hole in the wiring layer.

Optionally, the first binding area is located at the end portion of the flexible circuit board.

Optionally, a partial area of the flexible circuit board adjacent to the first binding area comprises the first ground layer, the wiring layer and the second ground layer that are laminated sequentially in that order.

In a second aspect, the present disclosure provides a display module, including a display panel and the flexible circuit board provided in the first aspect of the present disclosure.

In a third aspect, the present disclosure provides a display device, including the display module provided in the second aspect of the present disclosure.

The beneficial effects of the present disclosure are as follows:
in the embodiments of the present disclosure, it can timely and effectively reset the display panel when the ESD occurs, thereby effectively improving the anti-ESD capability, effectively reducing the risk of electrostatic damage to the display panel, and further improving the reliability of the product.

### BRIEF DESCRIPTION OF THE DRAWINGS

The present disclosure are further described in detail below with reference to the accompanying drawings.

FIG. 1 is a schematic diagram showing a switch circuit in a flexible circuit board provided in an embodiment of the present disclosure.

FIG. 2 is a schematic diagram showing wiring of a switch circuit in a flexible circuit board provided in an embodiment of the present disclosure.

FIG. 3 is a schematic diagram showing an ESD protection circuit and an ESD detection circuit in a flexible circuit board provided in an embodiment of the present disclosure.

FIG. 4 is a schematic diagram showing signal waveforms during the reset process of the DDIC.

FIG. 5 is a schematic diagram showing the area division of the flexible circuit board provided in an embodiment of the present disclosure.

FIG. 6 is a schematic cross-sectional view of a three-layer structure area in a flexible circuit board provided in an embodiment of the present disclosure.

### DETAILED DESCRIPTION

In the following, the terms “on”, “formed on” and “disposed on” in the present disclosure may mean that one layer is directly formed or disposed on another layer, or may mean that one layer is indirectly formed or disposed on another layer, i.e., there is another layer between the two layers.

It should be noted that, although the terms “first”, “second”, etc. may be used herein to describe various parts, components, elements, areas, layers and/or parts, these parts, components, elements, areas, layers and/or parts should not be limited by these terms. Instead, these terms are used to distinguish one part, component, element, area, layer and/or part from another. Thus, for example, the first part, first component, first element, first area, first layer and/or first part discussed below may be referred to as the second part, second component, second element, second area, second layer and/or second part without departing from the teachings of the present disclosure.

In the present disclosure, unless otherwise specified, the term “arranged in a same layer” used means that two layers, parts, components, elements or parts can be formed by the same preparation process (such as a patterning process, etc.), and the two layers, parts, components, elements or parts are generally formed of the same material. For example, two or more functional layers are arranged in the same layer, which means that these functional layers arranged in the same layer can be formed using the same material layer and the same preparation process, thereby simplifying the preparation process of the display substrate.

In the present disclosure, unless otherwise specified, the expression “patterning process” generally includes steps such as photoresist coating, exposure, development, etching, photoresist stripping, etc. The expression “a single patterning process” means a process of forming patterned layers, components, members, etc. using one mask.

An Organic Light-Emitting Diode (OLED) display panel can be electrically connected to a Display Driver Integrated Circuit (DDIC) through a Flexible Printed Circuit (FPC), so that the driver integrated circuit is arranged at the backlight side to achieve a narrow frame and a higher screen-to-body ratio. However, the inventors found that the OLED display panel in the related art has insufficient ESD resistance. Although the OLED display panel in the related art has made some designs to improve the ESD resistance, for example, the first binding area of the FPC used to bind with the OLED display panel is located in the bending area, and the outer side of the bending area is coated with Metal Cover Layer (MCL) glue (bending area protective glue), which provides some level of ESD protection; however, the ESD protection effect remains inadequate, and the product may fail ESD testing.

In view of this, embodiments of the present disclosure provide a flexible circuit board, including an electrostatic discharge protection circuit, an electrostatic discharge detection circuit and a switch circuit;
an input end of the electrostatic discharge detection circuit is coupled to an output end of the electrostatic discharge protection circuit, and an output end of the electrostatic discharge detection circuit is coupled to a control end of the switch circuit;
a first end of the switch circuit, a reset signal output end of an application processor, and a reset signal input end of a DDIC are coupled to a first node, and a second end of the switch circuit is coupled to a ground.

According to the embodiments of the present disclosure, it can timely and effectively reset the display panel when the ESD occurs, thereby effectively improving the anti-ESD capability, effectively reducing the risk of electrostatic damage to the display panel, and further improving the reliability of the display device.

In a specific example, the flexible circuit board provided in the embodiments of the present disclosure is a flexible circuit board used to connect an OLED display panel and a DDIC in a mobile phone. The display device of the mobile phone includes a DDIC and an OLED display panel. The DDIC is connected to the Application Processor (AP) of the mobile phone through the Mobile Industry Processor Interface (MIPI) to receive display data. It should be noted that the flexible circuit board provided in the embodiments of the present disclosure can be applied to various types of display panels, and the arrangement thereof can be selected according to actual needs. For example, in addition to the OLED display panel, the flexible circuit board provided in the embodiments of the present disclosure can also be applied to other types of display panels such as a Quantum Dot Light Emitting Diode (QLED) display panel and a Micro Light Emitting Diode (Micro LED) display panel to resist the ESD.

In a possible implementation, the switch circuit includes a first switch transistor, a control electrode of the first switch transistor is coupled to the output end of the electrostatic discharge detection circuit, a first electrode of the first switch transistor is coupled to the first node, and the second electrode of the first switch is coupled to the ground. This is conducive to improving the response speed of the switch circuit and ensuring the timeliness of resetting the display panel when the ESD occurs.

In a possible implementation, the first switch transistor is an N-type transistor, which is more conducive to improving the response speed of the switch circuit and ensuring the timeliness of resetting the display panel when the ESD occurs.

In a possible implementation, the flexible circuit board further includes a first resistor and a first capacitor, wherein the first resistor is coupled between the reset signal output end of the application processor and the first node, a first end of the first capacitor is coupled to the first node, and a second end of the first capacitor is coupled to the ground. Thus, the first resistor and the first capacitor can be used to protect a switching circuit including a switching transistor, for example, to prevent the switching transistor and other devices in the switching circuit from being broken down.

In the following, in combination with the above implementation, the display panel is considered as an OLED display panel as an example, the electrostatic discharge protection circuit structure and working principle of the flexible circuit board provided by the embodiments of the present disclosure are exemplarily described.

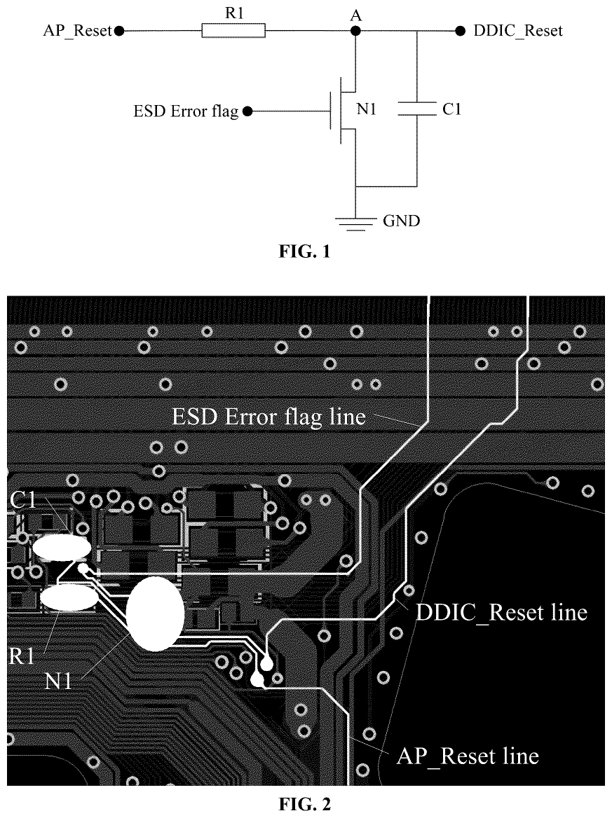

For example, as shown in FIGS. 1 and 2, the switch circuit includes an N-type transistor N1, such as an NMOS tube, the gate of the N-type transistor N1 is coupled to an (e.g., a General-Purpose Output (GPO) type) output end (ESD Error flag) of an electrostatic release detection circuit, the source electrode of the N-type transistor N1 is coupled to the ground GND, the drain electrode of the N-type transistor N1, the second end of the first resistor R1, the reset signal input end DDIC_Reset of the DDIC, and the first end of the first capacitor C1 are coupled to the first node A, the first end of the first resistor R1 is coupled to the reset signal output end AP_Reset of the application processor, and the second end of the first capacitor C1 is coupled to the ground (GND).

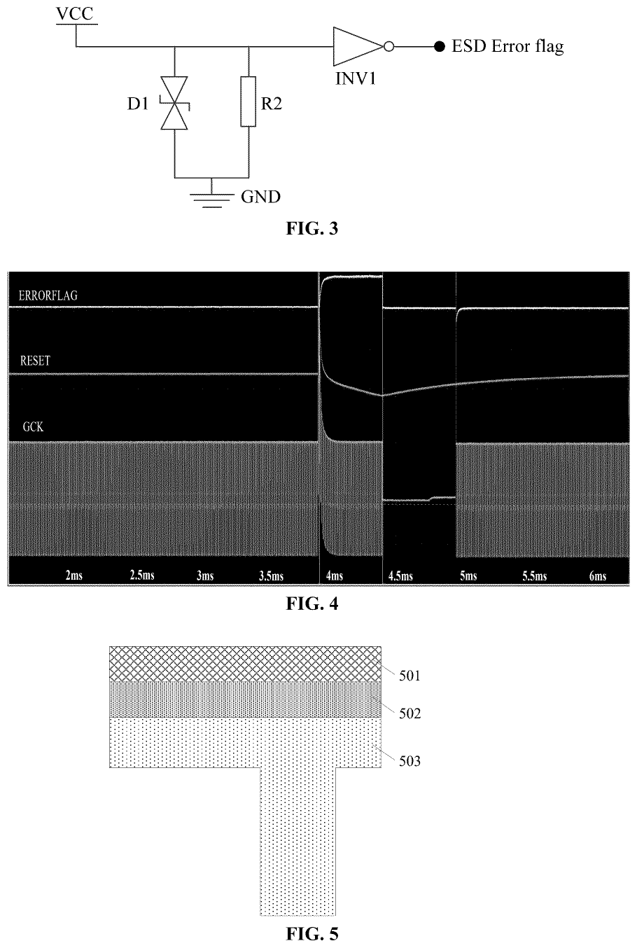

For example, as shown in FIG. 3, the electrostatic discharge protection circuit includes a first transient voltage suppression diode D1 and a second resistor R2, wherein the first end of the first transient voltage suppression diode D1 is coupled to the power supply end VCC, the second end of the first transient voltage suppression diode D1 is grounded (GND), the first end of the second resistor R2 is coupled to the power supply end VCC and the input end of the electrostatic release detection circuit, and the second end of the second resistor R2 is grounded (GND). For example, the first transient voltage suppression diode D1 is a bipolar transient voltage suppression diode. When the ESD does not occur, the first transient voltage suppression diode D1 is cut off or turned off, and the electrostatic release protection circuit continues to output a high level signal. When the ESD occurs, the first transient voltage suppression diode D1 is turned on, so that the electrostatic release protection circuit outputs a low level signal. After the ESD ends, the first transient voltage suppression diode D1 returns to the cut-off state, and the electrostatic release protection circuit resumes outputting a high level signal. That is, the electrostatic release protection circuit outputs a high level signal when the ESD does not occur, and outputs a low level signal when the ESD occurs.

Continuing to refer to FIG. 3, the electrostatic discharge detection circuit includes an inverter INV1, and an output end of the inverter INV1, as an (e.g., GPO type) output end ESD Error flag of the electrostatic discharge detection circuit, is coupled to the gate electrode of the N-type transistor N1.

Combined with FIGS. 1 to 3, and referring to FIG. 4:
when ESD does not occur, the electrostatic discharge protection circuit continuously outputs a high-level signal, the ERRORFLAG signal output by the (e.g., GPO type) output end ESD Error flag of the electrostatic discharge detection circuit is a low-level signal, the N-type transistor N1 is turned off, the input signal RESET of the reset signal input end DDIC_Reset of the DDIC is a high-level signal output by the reset signal output end AP_Reset of the AP, the DDIC is in a normal working state, and the normal output includes driving signals such as the clock signal GCK to drive the OLED display panel to display normally, such as the interval before 4 ms in FIG. 4.

When the ESD occurs, the electrostatic discharge protection circuit outputs a low-level signal, the ERRORFLAG signal output by the (e.g., GPO type) output end ESD Error flag of the electrostatic discharge detection circuit becomes a high-level signal, the N-type transistor N1 is turned on, the input signal RESET of the reset signal input end DDIC_Reset of the DDIC is pulled down to ground, the DDIC enters the reset state, and the OLED display panel enters the sleep-in state, such as the interval between 4 ms-4.5 ms in FIG. 4. For example, when the input signal RESET of the reset signal input end DDIC_Reset of the DDIC is pulled down to ground, the DDIC sets the flag F to F=1.

After the ESD ends, the electrostatic discharge protection circuit resumes outputting a high-level signal, and the ERRORFLAG signal output by the (e.g., GPO type) output end ESD Error flag of the electrostatic discharge detection circuit turns back to be a low-level signal, the N-type transistor N1 is turned off, and the input signal RESET of the reset signal input end DDIC_Reset of the DDIC turns back to be a high-level signal output by the reset signal output end AP_Reset of the AP, and the DDIC resumes normal working state, and the normal output includes the driving signal such as the clock signal GCK to drive the OLED display panel to display normally, such as the interval after 5 ms in FIG. 4; for example, the interval of 4.5 ms-5 ms in FIG. 4 is a reset process or a reset preparation interval. For example, when the input signal RESET of the reset signal input end DDIC_Reset of the DDIC turns back to be a high-level signal output by the reset signal output end AP_Reset of the AP, the DDIC sets the flag bit F to F=0, and the AP reads back to F=0 and performs a software reset action, and the DDIC resumes normal working state after executing the power-on procedure.

In a possible implementation, the flexible circuit board includes a first binding area which is located at an end position of one side of the flexible circuit board and used for binding to a display panel, and at least a portion of the area of the flexible circuit board that is near the first binding area includes a first ground layer, a wiring layer, and a second ground layer that are laminated sequentially in that order.

Therefore, from the perspective of circuit design, the flexible circuit board provided by the embodiments of the present disclosure realizes timely and effective reset of the display panel when the ESD occurs through the design of the switching circuit, thereby effectively improving the anti-ESD capability. The flexible circuit board provided by the embodiments of the present disclosure also improves the anti-ESD capability from the perspective of hardware stacking design by designing at least a portion of the area adjacent to the first binding area as a three-layer structure including a first ground layer, a wiring layer and a second ground layer.

In a possible implementation, the first ground layer and the second ground layer are electrically connected through a via hole provided in the wiring layer, thereby further improving the ESD resistance of the three-layer structure.

In a possible implementation, the first binding area is located at an end position of the flexible circuit board.

In a possible implementation, a partial area of the flexible circuit board adjacent to the first binding area includes a first ground layer, a wiring layer, and a second ground layer that are laminated sequentially in that order.

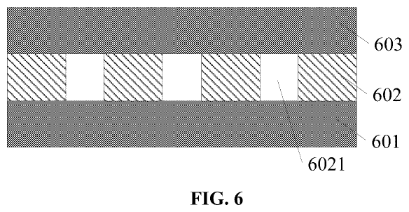

Taking the display panel as an OLED display panel for example, the FPC includes a first binding area for binding to the OLED display panel and a second binding area for binding to the DDIC, each of the first binding area and the second binding area respectively includes a plurality of binding pins, wherein the first binding area is located in the bending area, and the FPC in the related art is of a two-layer structure, a bottom layer thereof is a wiring layer, and a top layer thereof is a grounding layer; although the MCL glue may be applied to the outer side of the bending region to provide some degree of ESD protection, there remains a risk that ESD occurring in the bending region could enter the wiring layer and damage signal lines. In the above methods according to the embodiments of the present disclosure, a partial area of the FPC with a certain width adjacent to the first binding area is designed as a three-layer structure including a first grounding layer, a wiring layer and a second grounding layer, that is, the bottom layer and the top layer are grounding layers respectively, and the middle layer is a wiring layer wrapped by grounding layers on both sides. Therefore, when the ESD occurs, static electricity can be conducted away through the upper and lower grounding layers, which can further enhance the anti-ESD capability, especially the anti-ESD capability of the bending area. For example, as shown in FIG. 5, the area 502 of the FPC adjacent to the first binding area 501 is designed as a three-layer structure, and the remaining area 503 is still a two-layer structure including a wiring layer and a grounding layer. As shown in FIG. 6, in the area 502, the first grounding layer 601 and the second grounding layer 603 are electrically connected through a via hole 6021 in the wiring layer 602. It can be understood that FIG. 6 is only a schematic diagram of the arrangement of the film layer and the via hole, and the signal lines in the wiring layer 602 are insulated from the connectors such as metal connectors in the via hole 6021, the first grounding layer 601, and the second grounding layer 603.

Embodiments of the present disclosure provides a display module, including a display panel and a flexible circuit board provided in the above embodiments. The display panel is, for example, an OLED display panel. For example, the OLED display panel includes a display area and a frame area surrounding the display area. The frame area at one side is provided with a panel binding area. For example, the side where the panel binding area is provided is called a Data Pad (DP) side (data binding side), corresponding to, for example, the lower frame side of the OLED display panel of the mobile phone. The panel binding area includes a plurality of binding pins. The binding pins of the panel binding area are bound to the binding pins of the first binding area of the flexible circuit board through Chip On Film (COF). The flexible circuit board realizes the electrical connection between the OLED display panel and the DDIC.

For example, regarding the OLED display panel,
the OLED display panel includes a substrate and film layers such as a driving circuit layer, a pixel definition layer, an anode, a light-emitting device layer, a cathode and an encapsulation layer arranged on the substrate.

The flexible substrate may be made of materials such as polyimide (PI), polyethylene naphthalate (PEN), thermoplastic polyester (PET), etc., or may be a rigid substrate made of materials such as glass and quartz. The OLED display panel may further include a barrier layer and a buffer layer located between the substrate and the driving circuit layer. For example, the barrier layer and the buffer layer can be formed on the entire surface of the substrate. For example, the barrier layer can be made of inorganic insulating materials such as silicon oxide, silicon nitride, or silicon oxynitride, and the buffer layer can also be made of inorganic insulating materials such as silicon oxide, silicon nitride, or silicon oxynitride. The barrier layer is beneficial to blocking water and oxygen from entering the OLED formed later from the bottom. The buffer layer is beneficial to the quality of subsequent material deposition.

The driving circuit layer may also be referred to as a Thin Film Transistor (TFT) layer, including an active layer formed on the buffer layer by a patterning process, a Gate Insulating (GI) layer formed on the active layer by deposition or the like, a gate electrode of the thin film transistor formed on the gate insulating layer by a patterning process, an Inter-Layer Dielectric (ILD) layer formed on the gate electrode by deposition or the like, a source-drain metal layer formed on the ILD layer, and a Planarization (PLN) layer covering the source-drain metal layer and the exposed ILD layer, wherein the source-drain metal layer forms the source electrode and drain electrode of the thin film transistor, for example, the source electrode is electrically connected to the active layer through a via hole in the ILD layer. Among them, the active layer may be made of materials such as polysilicon and metal oxides, the gate insulating layer may be made of inorganic insulating materials such as silicon oxide, silicon nitride or silicon oxynitride, and the ILD layer may be made of inorganic insulating materials such as silicon oxide, silicon nitride or silicon oxynitride. The gate material includes metals or alloy materials such as aluminum, titanium, and cobalt. The PLN layer may be made of, for example, an organic material.

The anode is, for example, a metal oxide such as ITO, IZO, or a metal such as Ag, Al, Mo, or an alloy thereof. The anode is, for example, electrically connected to the drain electrode through a via hole in the PLN layer.

The pixel definition layer may be formed by a patterning process and surrounds the anode. For example, the material of the pixel definition layer may include organic insulating materials such as negative photoresist, polyimide, and epoxy resin.

The light-emitting device layer is formed on the anode exposed by the opening of the pixel definition layer. For example, the light-emitting device can be formed on the anode in the opening of the pixel definition layer by inkjet printing or evaporation, and the light-emitting device includes, for example, a light-emitting layer, and may further include an auxiliary light-emitting layer that helps the light-emitting layer emit light, and the auxiliary light-emitting layer includes, for example, one or more of an electron transport layer, an electron injection layer, a hole transport layer, and a hole injection layer. The light-emitting layer and the auxiliary light-emitting layer are, for example, organic material layers.

For example, the cathode is formed on the entire surface of the OLED display panel, covering the light-emitting device layer and the pixel definition layer. The material of the cathode may include metals such as Mg, Ca, Li or Al or their alloys, or metal oxides such as IZO and ZTO, or organic materials with conductive properties such as PEDOT/PSS (poly 3, 4-ethylenedioxythiophene/polystyrene sulfonate).

The encapsulation layer (Thin Film Encapsulation (TFE) layer) is located on the cathode. For example, the encapsulation layer includes a first inorganic encapsulation layer, an organic encapsulation layer and a second inorganic encapsulation layer. For example, the first inorganic encapsulation layer and the second inorganic encapsulation layer are formed by deposition or the like. The organic encapsulation layer is formed by inkjet printing. For example, the first inorganic encapsulation layer and the second inorganic encapsulation layer can be formed of inorganic materials such as silicon nitride, silicon oxide, and silicon oxynitride, and the organic encapsulation layer can be formed of organic materials such as polyimide (PI) and epoxy resin. Thus, the first inorganic encapsulation layer, the organic encapsulation layer and the second inorganic encapsulation layer form a composite encapsulation layer, which can form multiple protections for the functional structure of the display panel and has a better encapsulation effect.

For example, the OLED display panel further includes a Cover Glass (CG) located on the encapsulation layer.

Embodiments of the present disclosure further provide a display device, including the display panel provided in the above embodiments. The display device can be any product or component with a display function, such as a mobile phone, a tablet computer, a television, a monitor, a notebook computer, a digital photo frame, a navigator, etc., and the present disclosure is not limited thereto.

It should be noted that the above-described embodiments of the present disclosure are merely examples provided to clearly illustrate the present disclosure and are not intended to limit the implementation methods thereof. For those skilled in the art, other various modifications or alterations may be made based on the above description. It is impossible to exhaust all possible embodiments here, but any obvious modifications or alterations that fall within the scope of the technical solutions disclosed herein shall still be considered within the protective scope of the present disclosure.

1. A flexible circuit board, comprising an electrostatic discharge protection circuit, an electrostatic discharge detection circuit and a switch circuit;
an input end of the electrostatic discharge detection circuit is coupled to an output end of the electrostatic discharge protection circuit, and an output end of the electrostatic discharge detection circuit is coupled to a control end of the switch circuit;
a first end of the switch circuit, a reset signal output end of an application processor, and a reset signal input end of a Display Driver Integrated Circuit (DDIC) are coupled to a first node, and a second end of the switch circuit is coupled to the ground.

2. The flexible circuit board according to claim 1, wherein the switch circuit comprises a first switch transistor, a control electrode of the first switch transistor is coupled to the output end of the electrostatic discharge detection circuit, a first electrode of the first switch transistor is coupled to the first node, and a second electrode of the first switch transistor is coupled to the ground.

3. The flexible circuit board according to claim 2, wherein the first switch transistor is an N-type transistor.

4. The flexible circuit board according to claim 1, wherein the flexible circuit board further comprises a first resistor and a first capacitor, the first resistor is coupled between the reset signal output end of the application processor and the first node, a first end of the first capacitor is coupled to the first node, and a second end of the first capacitor is coupled to the ground.

5. The flexible circuit board according to claim 1, wherein the flexible circuit board comprises a first binding area that is located at an end position on one side of the flexible circuit board and used for binding with a display panel, and at least a portion of the flexible circuit board adjacent to the first binding area comprises a first ground layer, a wiring layer, and a second ground layer that are laminated sequentially in that order.

6. The flexible circuit board according to claim 5, wherein the first ground layer and the second ground layer are electrically connected through a via hole in the wiring layer.

7. The flexible circuit board according to claim 5, wherein the first binding area is located at the end portion of the flexible circuit board.

8. The flexible circuit board according to claim 7, wherein a portion of an area of the flexible circuit board that is adjacent to the first binding area comprises the first ground layer, the wiring layer and the second ground layer that are laminated sequentially in that order.

9. A display module, comprising a display panel and the flexible circuit board according to any one of claims 1.

10. A display device, comprising the display module according to claim 9.

11. The display module according to claim 9, wherein the switch circuit comprises a first switch transistor, a control electrode of the first switch transistor is coupled to the output end of the electrostatic discharge detection circuit, a first electrode of the first switch transistor is coupled to the first node, and a second electrode of the first switch transistor is coupled to the ground.

12. The display module according to claim 11, wherein the first switch transistor is an N-type transistor.

13. The display module according to claim 9, wherein the flexible circuit board further comprises a first resistor and a first capacitor, the first resistor is coupled between the reset signal output end of the application processor and the first node, a first end of the first in capacitor is coupled to the first node, and a second end of the first capacitor is coupled to the ground.

14. The display module according to claim 9, wherein the flexible circuit board comprises a first binding area that is located at an end position on one side of the flexible circuit board and used for binding with a display panel, and at least a portion of the flexible circuit board adjacent to the first binding area comprises a first ground layer, a wiring layer, and a second ground layer that are laminated sequentially in that order.

15. The display module according to claim 14, wherein the first ground layer and the second ground layer are electrically connected through a via hole in the wiring layer.

16. The display module according to claim 14, wherein the first binding area is located at the end portion of the flexible circuit board.

17. The display module according to claim 16, wherein a portion of an area of the flexible circuit board that is adjacent to the first binding area comprises the first ground layer, the wiring layer and the second ground layer that are laminated sequentially in that order.

18. The display device according to claim 10, wherein the switch circuit comprises a first switch transistor, a control electrode of the first switch transistor is coupled to the output end of the electrostatic discharge detection circuit, a first electrode of the first switch transistor is coupled to the first node, and a second electrode of the first switch transistor is coupled to the ground.

19. The display device according to claim 18, wherein the first switch transistor is an N-type transistor.

20. The display device according to claim 10, wherein the flexible circuit board further comprises a first resistor and a first capacitor, the first resistor is coupled between the reset signal output end of the application processor and the first node, a first end of the first capacitor is coupled to the first node, and a second end of the first capacitor is coupled to the ground.
